(19) United States
(12) Patent Application Publication
(10) Pub. No.: US 2020/0294773 A1
(43) Pub. Date: Sep. 17, 2020

(54) PLASMA PROCESSING METHOD AND PLASMA PROCESSING APPARATUS

(71) Applicant: Tokyo Electron Limited, Tokyo (JP)

(72) Inventors: Hayato Hishinuma, Kurokawa-gun (JP); Hisashi Hirose, Kurokawa-gun (JP)

(21) Appl. No.: 16/809,726

(22) Filed: Mar. 5, 2020

(30) Foreign Application Priority Data
Mar. 11, 2019 (JP) 2019-043693

(51) Int. Cl. H01J 37/32; H01L 21/311

(52) U.S. Cl. CPC H01J 37/32449; H01L 21/31144; H01J 37/32541

(57) ABSTRACT

A target object processed by performing a plasma processing method includes a first layer made of silicon oxide and a second layer containing carbon. A processing sequence performed repeatedly includes: etching the target object with the second layer as a mask by forming plasma from a first gas; and etching, after the etching by forming the plasma from the first gas, the target object by forming plasma from a second gas. The first gas includes a gas containing a carbon atom and a fluorine atom. The second gas includes a gas containing a carbon atom, a fluorine atom and a hydrogen atom. High-order fluorocarbon is generated by the plasma from the first gas in the etching by forming the plasma from the first gas. Low-order fluorocarbon or low-order hydrofluorocarbon is generated by the plasma from the second gas in the etching by forming the plasma from the second gas.

### CROSS-REFERENCE TO RELATED APPLICATION

This application claims the benefit of Japanese Patent Application No. 2019-043693 filed on Mar. 11, 2019, the entire disclosure of which is incorporated herein by reference.

### TECHNICAL FIELD

The various aspects and embodiments described herein pertain generally to a plasma processing method and a plasma processing apparatus.

### BACKGROUND

When etching a multilayered film by using a plasma processing apparatus, a plurality of holes having different depths may be formed in an oxide layer included in the multilayered film. A plasma processing method described in Patent Document 1 is directed to a method of forming multiple holes having different heights in a multilayered film. The multilayered film has an oxide layer, a plurality of etching stop layers and a mask layer. The etching stop layers are made of tungsten. In this method, by supplying a processing gas into a processing vessel and forming plasma from the processing gas, the multilayered film ranging from a top surface of the oxide layer to the plurality of etching stop layers is etched. The multiple holes having the different depths are formed in the oxide layer at the same time through this etching. The processing gas includes a fluorocarbon-based gas, a rare gas, oxygen and nitrogen.

Patent Document 1: Japanese Patent Laid-open Publication No. 2014-090022

### SUMMARY

In an exemplary embodiment, there is provided a plasma processing method of processing a processing target object. The processing target object comprises a first layer and a second layer. The second layer is provided with multiple openings and is provided on a top surface of the first layer. The top surface is exposed through the multiple openings. The first layer is provided with multiple etching stop layers. Within the first layer, lengths from the multiple etching stop layers to the top surface are different. The first layer is made of silicon oxide. The second layer is made of a material containing carbon. The method comprises a processing sequence which is performed repeatedly within a chamber of a plasma processing apparatus in which the processing target object is accommodated. The processing sequence comprises: etching the processing target object through the multiple openings with the second layer as a mask by forming plasma from a first gas; and etching, after the etching by forming the plasma from the first gas, the processing target object by forming plasma from a second gas. The first gas includes a gas containing a carbon atom and a fluorine atom. The second gas includes a gas containing a carbon atom, a fluorine atom and a hydrogen atom. High-order fluorocarbon is generated by the plasma from the first gas in the etching performed by forming the plasma from the first gas. Low-order fluorocarbon or low-order hydrofluorocarbon is generated by the plasma from the second gas in the etching performed by forming the plasma from the second gas.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a flowchart illustrating an example of a plasma processing method according to an exemplary embodiment;

FIG. 2 is a diagram illustrating a configuration example of a plasma processing apparatus in which the plasma processing method shown in FIG. 1 is performed;

FIG. 3 is a diagram illustrating an example structure of a processing target object on which the plasma processing method of FIG. 1 is performed;

FIG. 4 is a diagram illustrating an example structure obtained while etching the processing target object of FIG. 3 by the plasma processing method shown in FIG. 1;

FIG. 5 is a diagram illustrating an example structure obtained while further etching the processing target object of FIG. 4 by the plasma processing method shown in FIG. 1; and

FIG. 6 is a diagram illustrating an example structure obtained by performing the plasma processing method of FIG. 1 on the processing target object shown in FIG. 3.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described. The exemplary embodiments provide a plasma processing method of processing a processing target object. The processing target object has a first layer and a second layer. The second layer is provided with a plurality of openings and is provided on a top surface of the first layer. Through the openings of the second layer, the top surface of the first layer is exposed. The first layer has a plurality of etching stop layers. Within the first layer, lengths from the respective etching stop layers to the top surface of the first layer are all different. The first layer is made of silicon oxide. The second layer contains carbon. In this plasma processing method, a processing sequence is repeatedly performed within a chamber of a plasma processing apparatus in which the processing target object is accommodated. The processing sequence includes etching the processing target object through the openings with the second layer as a mask by forming plasma from a first gas (sometimes referred to as process A). The processing sequence further includes etching, after etching the processing target object by the plasma from the first gas, the processing target object by forming plasma from a second gas (sometimes referred to as process B). The first gas includes a gas containing a carbon atom and a fluorine atom. The second gas includes a gas containing a carbon atom, a fluorine atom and a hydrogen atom. In the etching performed by forming the plasma from the first gas, high-order fluorocarbon is generated by the plasma from the first gas. In the etching performed by forming the plasma from the second gas, low-order fluorocarbon or low-order hydrofluorocarbon is generated by the plasma from the second gas.

In the process A, by the etching with the plasma from the first gas, the etching upon the first layer trough the openings of the second layer can be performed.

In the process A, however, the high-order fluorocarbon may be generated by the plasma from the first gas. The high-order fluorocarbon is polymer having a high attachment coefficient (hereinafter, sometimes referred to as first polymer). In the process A, this first polymer attaches on the second layer and a side surface of a hole formed by performing the process A. However, it is difficult for this first polymer to reach a bottom of the hole. If the process A is carried on, the first polymer keeps on attaching on a top surface of the second layer and side surfaces of the openings, clogging the openings. Accordingly, it may be difficult to carry on the etching upon the first layer.

Further, since it is difficult for the first polymer to reach the bottom of the hole, selectivity with respect to the etching stop layer is relatively low in the etching of the process A. Therefore, in case that the etching stop layer is exposed through the hole, this etching stop layer may not be protected by the first polymer, and, as a result, this etching stop layer may be etched.

Particularly, in the above-described method, a plurality of holes having different lengths from the top surface of the first layer to the etching stop layers are formed in parallel, not one by one. Therefore, the etching stop layer in a hole having a comparatively short length may be excessively etched by the etching of the process A.

In the process B following the process A, low-order fluorocarbon or low-order hydrofluorocarbon is generated by the plasma from the second gas. The low-order fluorocarbon or the low-order hydrofluorocarbon is polymer having a low attachment coefficient (hereinafter, sometimes referred to as second polymer). In the process B, though it is difficult for this second polymer to attach on the second layer and the side surface of the hole formed by the process A, the second polymer easily reaches the bottom of the hole. Meanwhile, in case that the etching stop layer is exposed through the hole, this second polymer may attach on the etching stop layer through the hole.

As stated above, the second polymer easily reaches the bottom of the hole. Accordingly, in case that the etching stop layer is exposed through the hole, the second polymer may be deposited on the etching stop layer (bottom of the hole), and, thus, the etching stop layer can be protected by the deposited second polymer.

As described above, in the etching performed in the process A, the selectivity with respect to the etching stop layer is relatively low. Further, in the etching performed in the process A, the opening of the second layer (mask) may be clogged, and it may be difficult to carry on the etching. As a resolution, by performing the process B after performing the process A appropriately, the opening of the second layer which is clogged in the process A can be enlarged. Further, in case that the etching stop layer is exposed through the hole formed by the process A, a protective film (second polymer) can be formed on the etching stop layer by performing the process B. Therefore, at the beginning of the process A performed after the process B, the opening of the second layer is already enlarged. At this time, in case that the etching stop layer is exposed through the hole in the etching of the process A, the protective film (second polymer) is already formed on the etching stop layer. Therefore, in the process A performed after the process B, the excessive etching upon the etching stop layer can be suppressed by the protective film (second polymer) while the opening of the second layer is suppressed from being clogged.

Furthermore, in this method, the above-stated processing sequence can be performed repeatedly. Accordingly, by performing the present method, the holes having the different lengths can be formed in parallel, not one by one. In this case, during a period until a hole having the longest length from the top surface of the first layer is formed, it is possible to avoid the clogging of the opening while suppressing the etching stop layer in the hole having the comparatively short length from being excessively etched.

In the plasma processing method according to the exemplary embodiment, the first gas may include at least one of a C₄F₆ gas or a C₄F₈ gas.

In the plasma processing method according to the exemplary embodiment, the second gas may include at least one of a CHF₃ gas, a CH₂F₂ gas or a CH₃F gas.

In the plasma processing method according to the exemplary embodiment, the second gas may further include at least one of a CO gas, a CO₂ gas, an O₂ gas, a N₂ gas, or a H₂ gas.

In the plasma processing method according to the exemplary embodiment, the etching stop layer may be made of tungsten.

In the plasma processing method according to the exemplary embodiment, in the etching performed by forming the plasma from the first gas, the high-order fluorocarbon mainly attaches on the second layer. In the etching performed by forming the plasma from the second gas, the low-order fluorocarbon or the low-order hydrofluorocarbon attaches on the etching stop layer through the hole formed by performing the processing sequence.

In the exemplary embodiment, a plasma processing apparatus is provided. The plasma processing apparatus includes a chamber, a placing table, a gas supply system, a high frequency power supply and a controller. The placing table is provided within the chamber. The gas supply system is configured to supply a first gas and a second gas into the chamber. The high frequency power supply is configured to supply a high frequency power to excite the first gas and the second gas. The controller is configured to control the gas supply system and the high frequency power supply. The controller controls the gas supply system and the high frequency power supply to perform a processing sequence repeatedly to etch a processing target object, which is placed on the placing table and provided with a first layer and a second layer, by forming plasma from the first gas and plasma from the second gas. The second layer is provided with multiple openings and is provided on a top surface of the first layer. The top surface is exposed through the multiple openings. The first layer is provided with multiple etching stop layers. Within the first layer, lengths from the multiple etching stop layers to the top surface are different. The first layer is made of silicon oxide. The second layer is made of a material containing carbon. The processing sequence comprises: etching the processing target object through the multiple openings with the second layer as a mask by forming plasma from the first gas; and etching, after the etching by forming the plasma from the first gas, the processing target object by forming plasma from the second gas. The first gas includes a gas containing a carbon atom and a fluorine atom. The second gas includes a gas containing a carbon atom, a fluorine atom and a hydrogen atom. High-order fluorocarbon is generated by the plasma from the first gas in the etching performed by forming the plasma from the first gas. Low-order fluorocarbon or low-order hydrofluorocarbon is generated by the plasma from the second gas in the etching performed by forming the plasma from the second gas.

In the plasma processing apparatus according to the exemplary embodiment, the first gas may include at least one of a C₄F₆ gas or a C₄F₈ gas.

In the plasma processing apparatus according to the exemplary embodiment, the second gas may include at least one of a CHF₃ gas, a CH₂F₂ gas or a CH₃F gas.

In the plasma processing apparatus according to the exemplary embodiment, the second gas may further include at least one of a CO gas, a CO₂ gas, an O₂ gas, a N₂ gas, or a H₂ gas.

In the plasma processing apparatus according to the exemplary embodiment, the high-order fluorocarbon attaches mainly on the second layer in the etching performed by forming the plasma from the first gas. In the etching performed by forming the plasma from the second gas, the low-order fluorocarbon or the low-order hydrofluorocarbon attaches on the etching stop layer through the hole formed by performing the processing sequence.

Now, various exemplary embodiments will be described in detail with reference to the accompanying drawings. In the various drawings, same or corresponding parts will be assigned same reference numerals.

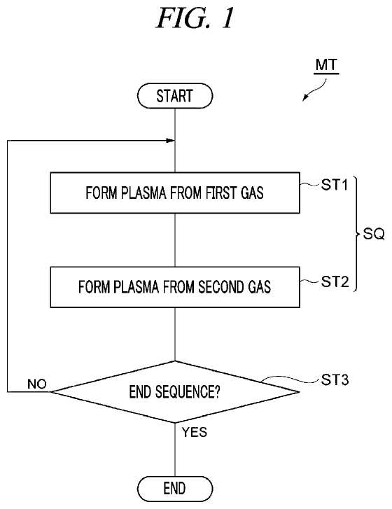

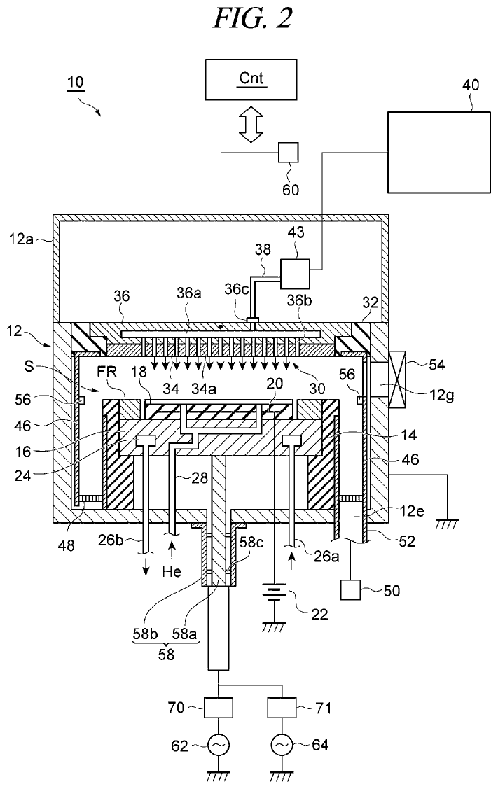

FIG. 1 is a flowchart illustrating a plasma processing method (hereinafter, referred to as “method MT”) according to an exemplary embodiment. The method MT shown in FIG. 1 can be performed by using, for example, a plasma processing apparatus 10 shown in FIG. 2. First, referring to FIG. 2, a configuration of the plasma processing apparatus 10 will be explained.

FIG. 2 is a diagram illustrating the plasma processing apparatus 10 according to the exemplary embodiment. The plasma processing apparatus 10 shown in FIG. 2 is configured as a capacitively coupled parallel plate type plasma processing apparatus, and is equipped with a substantially cylindrical chamber 12. The chamber 12 has, for example, an anodically oxidized aluminum surface. The chamber 12 is frame-grounded.

The plasma processing apparatus 10 is equipped with the chamber 12, a grounding conductor 12a, an exhaust port 12e, a carry-in/out opening 12g, a supporting member 14, a placing table 16, an electrostatic chuck 18, an electrode 20 and a DC power supply 22. The plasma processing apparatus 10 is also equipped with a coolant path 24, a pipeline 26a, a pipeline 26b, a gas supply line 28, an upper electrode 30, an insulating shield member 32, an electrode plate 34, multiple gas discharge holes 34a and an electrode supporting body 36.

The plasma processing apparatus 10 is further equipped with a gas diffusion space 36a, multiple gas through holes 36b, a gas inlet opening 36c, a gas supply line 38, a gas supply system 40, a splitter 43, a deposition shield 46, an exhaust plate 48, an exhaust device 50, an exhaust line 52 and a gate valve 54.

The plasma processing apparatus 10 is also equipped with a conductive member 56, a power feed rod 58, a rod-shaped conductive member 58a, a cylindrical conductive member 58b, an insulating member 58c, a DC power supply 60, a first high frequency power supply 62, a second high frequency power supply 64, a matching device 70, and a matching device 71. The plasma processing apparatus 10 is further equipped with a controller Cnt, a focus ring FR and a processing space S.

The supporting member 14 is placed on a bottom of the chamber 12. The supporting member 14 may have a cylindrical shape. The supporting member 14 may be made of an insulating material. The supporting member 14 supports the placing table 16.

The placing table 16 is provided within the chamber 12. The placing table 16 may be made of a metal such as aluminum. In the present exemplary embodiment, the placing table 16 constitutes a lower electrode.

The electrostatic chuck 18 is provided on a top surface of the placing table 16. The electrostatic chuck 18 and the placing table 16 constitute a placing table of the exemplary embodiment. The electrostatic chuck 18 has a structure in which the electrode 20 is embedded in a pair of insulating layers or a pair of insulating sheets.

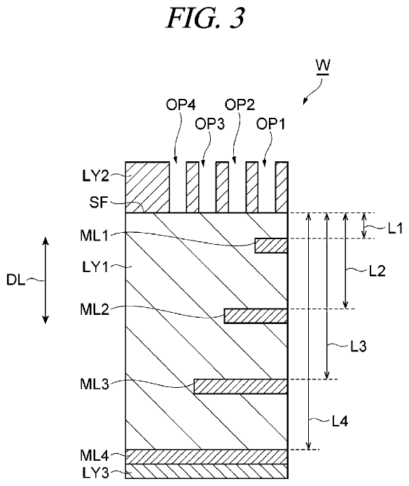

The electrode 20 may be a conductive film. The electrode 20 is electrically connected with the DC power supply 22. The electrostatic chuck 18 attracts and holds a processing target object (for example, a processing target object W shown in FIG. 3) by an electrostatic force generated by a DC voltage applied from the DC power supply 22.

The focus ring FR is disposed on the top surface of the placing table 16 to surround the electrostatic chuck 18. The focus ring FR is configured to improve etching uniformity. The focus ring FR may be made of, by way of non-limiting example, silicon or quartz.

The coolant path 24 is provided within the placing table 16. A coolant of a preset temperature, for example, cooling water from a chiller unit provided outside is supplied into and circulated in the coolant path 24 via the pipelines 26a and 26b. By controlling the temperature of the coolant circulated in the coolant path 24, a temperature of the processing target object placed on the electrostatic chuck 18 can be controlled.

Through the gas supply line 28, a heat transfer gas, for example, a He gas from a heat transfer gas supply mechanism (not shown) is supplied into a gap between a top surface of the electrostatic chuck 18 and a rear surface of the processing target object.

The upper electrode 30 is provided within the chamber 12. The upper electrode 30 is disposed above the placing table 16 serving as the lower electrode, facing the placing table 16. The placing table 16 and the upper electrode 30 are arranged to be substantially parallel to each other. Formed between the upper electrode 30 and the lower electrode is the processing space S in which plasma etching is performed on the processing target object.

The upper electrode 30 is supported at an upper portion of the chamber 12 with the insulating shield member 32 therebetween. The upper electrode 30 may include the electrode plate 34 and the electrode supporting body 36. The electrode plate 34 is in direct contact with the processing space S, and is provided with the multiple gas discharge holes 34a. The electrode plate 34 may be made of a conductor or semiconductor having low resistance and low Joule heat.

The electrode supporting body 36 is configured to support the electrode plate 34 in a detachable manner, and may be made of a conductive material such as, but not limited to, aluminum. The electrode supporting body 36 may have a water-cooling structure.

The gas diffusion space 36a is formed within the electrode supporting body 36. The gas diffusion space 36a communicates with the processing space S through the multiple gas through holes 36b and the multiple gas discharge holes 34a.

The multiple gas through holes 36b communicate with the multiple gas discharge holes 34a, respectively. The gas through holes 36b are formed at the electrode supporting body 36, and the gas discharge holes 34a are formed at the electrode plate 34.

The gas inlet opening 36c is connected with the gas supply line 38. The gas inlet opening 36c is formed at the electrode supporting body 36. Various kinds of gases output from the gas supply system 40 can be introduced into the gas diffusion space 36a through the gas inlet opening 36c.

The gas supply system 40 is configured to supply a first gas and a second gas for performing the method MT shown in FIG. 1 into the chamber 12. The gas supply system 40 is connected to the gas supply line 38 via the splitter 43.

The first gas includes a gas composed of a carbon atom and a fluorine atom. The first gas may include at least one of, for example, a C₄F₆ gas or a C₄F₈ gas.

The second gas includes a gas composed of a carbon atom, a fluorine atom and a hydrogen atom. The second gas may include at least one of, for example, a CHF₃ gas, a CH₂F₂ gas or a CH₃F gas.

The second gas may further include at least one of, for example, a CO gas, a CO₂ gas, an O₂ gas, a N₂ gas, or a H₂ gas.

The grounding conductor 12a is of a substantially cylindrical shape. The grounding conductor 12a extends upward from a sidewall of the chamber 12 to be higher than a height position of the upper electrode 30.

The deposition shield 46 is provided along an inner wall of the chamber 12 in a detachable manner. The deposition shield 46 is also provided on an outer side surface of the supporting member 14. The deposition shield 46 is configured to suppress an etching byproduct (deposit) from adhering to the chamber 12. The deposition shield 46 may be formed by coating, for example, an aluminum member with ceramics such as Y₂O₃.

At a bottom side of the chamber 12, the exhaust plate 48 is disposed between the supporting member 14 and the inner wall of the chamber 12. The exhaust plate 48 may be made of, for example, an aluminum member coated with ceramics such as Y₂O₃.

Within the chamber 12, the exhaust opening 12e is provided under the exhaust plate 48. The exhaust opening 12e is connected with the exhaust device 50 via the exhaust line 52.

The exhaust device 50 includes a vacuum pump such as a turbo molecular pump, and is capable of decompressing the inside of the chamber 12 to a required vacuum level.

The carry-in/out opening 12g is provided for the processing target object. The carry-in/out opening 12g is provided at the sidewall of the processing vessel 12. The carry-in/out opening 12g is opened or closed by the gate valve 54.

The conductive member 56 is provided at the inner wall of the chamber 12. The conductive member 56 is fixed to the inner wall 12 to be located on a substantially level with the processing target object in a height direction. The conductive member 56 is DC-connected to the ground and has an effect of suppressing an abnormal discharge.

The location of the conductive member 56 is not limited to the example shown in FIG. 2 as long as the conductive member 56 is provided in a plasma formation space. By way of example, the conductive member 56 may be provided near the placing table 16, for example, around the placing table 16. Alternatively, the conductive member 56 may be provided near the upper electrode 30. For example, the conductive member 56 may be provided at an outside of the upper electrode 30 in a ring shape.

The power feed rod 58 supplies a high frequency power to the placing table 16 serving as the lower electrode. The power feed rod 58 has a coaxial double pipe structure. The power feed rod 58 includes the rod-shaped conductive member 58a and the cylindrical conductive member 58b.

The rod-shaped conductive member 58a extends from an outside of the chamber 12 to an inside of the chamber 12 through the bottom of the chamber 12 in a substantially vertical direction. An upper end of the rod-shaped conductive member 58a is connected to the placing table 16.

The cylindrical conductive member 58b is disposed to be coaxial with the rod-shaped conductive member 58a, surrounding the rod-shaped conductive member 58a. The cylindrical conductive member 58b is supported at the bottom of the chamber 12. Two sheets of substantially annular insulating members 58c are disposed between the rod-shaped conductive member 58a and the cylindrical conductive member 58b. Accordingly, the rod-shaped conductive member 58a and the cylindrical conductive member 58b are electrically insulated.

Lower ends of the rod-shaped conductive member 58a and the cylindrical conductive member 58b are connected to the matching devices 70 and 71. The matching device 70 is connected to the first high frequency power supply 62. The matching device 71 is connected to the second high frequency power supply 64.

The first high frequency power supply 62 is configured to supply a high frequency power to excite the first gas and the second gas. The first high frequency power supply 62 generates a first high frequency power for plasma formation. A frequency of the first high frequency power is in a range from 27 MHz to 100 MHz, for example, 100 MHz.

The second high frequency power supply 64 is configured to generate a second high frequency power for ion attraction into the processing target object by applying a high frequency bias power to the placing table 16. A frequency of the second high frequency power is in a range from 400 kHz to 13.56 MHz, and may be for example, 3 MHz.

The DC power supply 60 is connected to the upper electrode 30. The DC power supply 60 is configured to apply a negative DC voltage to the upper electrode 30. With the above-described configuration, the two different high frequency powers are applied to the placing table 16 serving as the lower electrode, and the DC voltage is applied to the upper electrode 30.

The controller Cnt is a computer including a processor, a storage, an input device, a display device, and so forth. The controller Cnt controls the individual components of the plasma processing apparatus 10, for example, the power supply system, the gas supply system, and the driving system. Particularly, the controller Cnt is capable of controlling the gas supply system 40, the first high frequency power supply 62 and the second high frequency power supply 64.

The storage of the controller Cnt stores therein a control program for implementing various processings performed in the plasma processing apparatus 10 by the processor. The control program that can be executed by the processor includes a computer program for allowing each component of the plasma processing apparatus 10 to perform a processing according to processing conditions, i.e., a processing recipe.

The control program stored in the storage of the controller Cnt may particularly include a computer program for implementing a processing described in the flowchart of the method MT of FIG. 1. The controller Cnt executes the control program to etch the processing target object placed on the placing table 16 by forming the plasma from each of the first gas and the second gas supplied from the gas supply system 40. The controller Cnt controls the gas supply system 40 and the first high frequency power supply 62 to repeat a processing sequence SQ of the method MT shown in FIG. 1.

To perform an etching processing by using the plasma processing apparatus 10, the processing target object is placed on the electrostatic chuck 18. By supplying various kinds of gases from the gas supply system 40 into the chamber 12 at preset flow rates while evacuating the chamber 12 by the exhaust device 50, an internal pressure of the chamber 12 is set to be in a range from, e.g., 0.1 Pa to 50 Pa.

The first high frequency power is supplied to the lower electrode from the first high frequency power supply 62, and the second high frequency power is supplied to the lower electrode from the second high frequency power supply 64. The first DC voltage is applied to the upper electrode 30 from the DC power supply 60. Accordingly, a high frequency electric field is formed between the upper electrode 30 and the lower electrode, and the plasma from the various processing gases supplied into the processing space S can be formed. The processing target object can be etched by various ions and radicals in the plasma.

The method MT shown in FIG. 1 may be a method of etching the processing target object W having the structure shown in FIG. 3, for example. The processing target object W has a first layer LY1 and a second layer LY2. The first layer LY1 has a multiple number of etching stop layers (etching stop layers ML1 to ML4, etc.).

The etching stop layer ML3 is provided above the etching stop layer ML4. The etching stop layer ML2 is provided above the etching stop layer ML3. The etching stop layer ML1 is provided above the etching stop layer ML2. A top surface SF is provided above the etching stop layer ML1. By way of example, a film thickness of the etching stop layers ML1 to ML4 ranges from 30 nm to 80 nm.

Within the first layer LY1, lengths from the respective etching stop layers (the etching stop layers ML1 to ML4) to the top surface SF are all different. In the present exemplary embodiment, a length L1 from the etching stop layer ML1 to the top surface SF is shorter than a length L2 from the etching stop layer ML2 to the top surface SF. The length L2 is shorter than a length L3 from the etching stop layer ML3 to the top surface SF. The length L3 is shorter than a length L4 from the etching stop layer ML4 to the top surface SF. By way of example, the length L1 is in a range from 500 nm to 1000 nm, and the length L4 is in a range from 7500 nm to 8000 nm.

As stated above, in the method MT, a multiple number of holes (openings) (holes HL1 to HL4, etc.) having the different lengths from the top surface SF to the etching stop layers (the etching stop layer ML1, etc.) are formed in parallel, not one by one, as in the processing target object W shown in FIG. 3 to FIG. 6.

The second layer LY2 is provided on the top surface SF of the first layer LY1. The second layer LY2 is provided with a multiple number of openings (openings OP1 to OP4, etc.). The top surface SF is exposed through the openings (openings OP1 to OP4, etc.). By way of example, the openings OP1 to OP4 have a diameter ranging from 120 nm to 140 nm.

In the present exemplary embodiment, the opening OP1 is overlapped with the etching stop layer ML1 in a stacking direction DL of the multiple number of etching stop layers (etching stop layers ML1 to ML4, etc.) within the first layer LY1. The opening OP2 is overlapped with the etching stop layer ML2 in the stacking direction DL. The opening OP3 is overlapped with the etching stop layer ML3 in the stacking direction DL. The opening OP4 is overlapped with the etching stop layer ML4 in the stacking direction DL.

The first layer LY1 is made of silicon oxide. By way of non-limiting example, the first layer LY1 may be made of silicon dioxide (SiO₂). The second layer LY2 may be made of a material containing carbon. The second layer LY2 may be a carbon layer formed by, for example, CVD (Chemical Vapor Deposition). The etching stop layers ML1 to ML4 may be made of tungsten.

In the present exemplary embodiment, the processing target object W further includes a third layer LY3. The first layer LY1 is provided above this third layer LY3. To elaborate, the etching stop layer ML4 is provided on the third layer LY3.

Referring back to FIG. 1, the method MT will be discussed. The method MT is an example of a plasma processing method of processing the processing target object. To be more specific, the method MT is a method of etching the processing target object W placed on the placing table 16 by forming the plasma from the first gas and the plasma from the second gas. In the method MT, the multiple number of holes (holes HL1 to HL4, etc.) having the different lengths from the top surface SF to the etching stop layers (etching stop layers ML1 to ML4, etc.) are formed in parallel, not one by one, as in the processing target object W shown in FIG. 3 to FIG. 6.

The method MT includes the processing sequence SQ. The processing sequence SQ includes a process ST1 and a process ST2. The process ST2 is performed after the process ST1. The multiple number of holes (holes HL1 to HL4, etc.) are formed by performing the processing sequence SQ.

The method MT also includes a process ST3. The process ST3 is performed after the processing sequence SQ.

In the method MT, the processing sequence SQ is performed repeatedly (to be more specified, a preset number of times) in the chamber 12 of the plasma processing apparatus 10 in which the processing target object W shown in FIG. 3 is accommodated (placed on the placing table 16). The method MT can be performed under the control of the controller Cnt. In performing the etching according to the method MT, the controller Cnt particularly controls the gas supply system 40 and the first high frequency power supply 62.

In the process ST1 of the processing sequence SQ, the plasma from the first gas is formed, and the processing target object W is etched through the openings (opening OP1, etc.) of the second layer LY2 by using the second layer LY2 as a mask. Through the etching of the process ST1 using the plasma from the first gas, the etching upon the first layer LY1 through the multiple number of openings (openings OP1 to OP4, etc.) of the second layer LY2 can be performed.

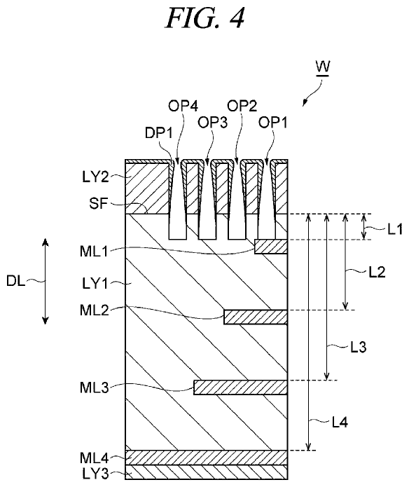

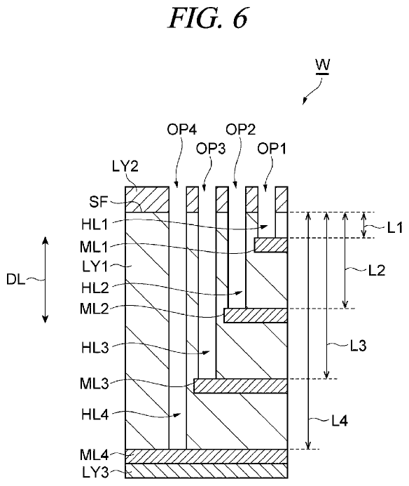

As stated above, in the process ST1, the etching upon the first layer LY1 is performed by the plasma from the first gas. In the process ST1, however, high-order fluorocarbon may be generated by the plasma from the first gas. The high-order fluorocarbon is first polymer mainly composed of CₓF_{y} (x is equal to or larger than 2) and has a high attachment coefficient. In the process ST1, the first polymer mainly attaches on the second layer LY2 and may also attach to a side surface of the hole such as the hole HL1 shown in FIG. 6 which is formed through the process ST1. As shown in FIG. 4, due to the adhesion of the first polymer, a deposit film DP1 of the first polymer is formed mainly on the second layer LY2 and, also, on the side surface of the hole such as the hole HL1 (particularly, at an upper portion of the corresponding side surface in the opening OP1 or the like). Further, the first polymer may not reach a bottom of the hole such as the hole HL1.

Accordingly, if the process ST1 is carried on over a relatively long period, the first polymer keeps on attaching on the top surface of the second layer LY2 and on the side surface of the hole such as the hole HL1 (particularly, at the upper portion of the corresponding side surface in the opening OP1 or the like), so that a thickness of the deposit film DP1 may be increased. In such a case, the opening such as the opening OP1 may be clogged with the deposit film DP1, and it may be difficult to carry on the etching upon the first layer LY1. The process ST1 may be continued for an appropriate time period unless the opening of the hole such as the hole HL1 formed by the etching of the process ST1 is clogged with the deposit film DP1.

Further, it is difficult for the first polymer to reach the bottom of the hole such as the hole HL1, and selectivity with respect to the etching stop layer such as the etching stop layer ML1 is relatively low in the etching of the process ST1. Thus, in case that the etching stop layer such as the etching stop layer ML1 is exposed through the hole such as the hole HL1, the corresponding etching stop layer is not protected by the first polymer, so that the corresponding etching stop layer may be etched.

Particularly, in the method MT, the multiple number of holes (corresponding to the hole HL1, etc.) having the different lengths from the top surface SF to the etching stop layers such as the etching stop layer ML1 are formed in parallel, not one by one. Therefore, in the hole (corresponding to the hole HL1, etc.) having a relatively short length, the etching stop layer such as the etching stop layer ML1 may be excessively etched by the etching of the process ST1.

The high frequency power for plasma formation from the first high frequency power supply 62 in the process ST1 may be in a range from, e.g., 300 W to 1000 W. Further, if the high frequency power is larger than 1000 W, the deposit film DP1 is formed at the upper portion and the sidewall of the second layer LY2 and the sidewall and the bottom of the hole such as the hole HL1. As a result, it may be difficult to carry on the etching.

In the process ST2 following the process ST1, the etching is performed on the processing target object W by forming the plasma from the second gas to remove the first polymer formed in the process ST1 and to suppress the excessive etching upon the etching stop layer in the process ST1.

In the process ST2, low-order fluorocarbon or low-order hydrofluorocarbon is generated by the plasma from the second gas while the deposit film DP1 formed in the opening such as the opening OP1 in the process ST1 is removed. The low-order fluorocarbon or the low-order hydrofluorocarbon is second polymer mainly composed of CF, CF₂, CF₃, CHF or CHF₂, and has a low attachment coefficient. In the process ST2, though it is difficult for this second polymer to attach on the second layer LY2 and the side surface of the hole such as the hole HL1 formed by the process ST1, the second polymer easily reaches the bottom of the hole such as the hole HL1. Due to the adhesion of this second polymer, a deposit film DP2 of the second polymer is formed at the bottom of the hole such as the hole HL1 and a lower portion of the hole such as the hole HL1 extending from the corresponding bottom.

Meanwhile, in case that the etching stop layer such as the etching stop layer ML1 is exposed through the hole such as the hole HL1, the second polymer may attach on the etching stop layer such as the etching stop layer ML1 through the corresponding hole. In such a case, the deposit film DP2 of the second polymer is formed on the etching stop layer such as the etching stop layer ML1 through the hole such as the hole HL1.

As stated above, the second polymer easily reaches the bottom of the hole such as the hole HL1. Accordingly, if the etching stop layer such as the etching stop layer ML1 is exposed through the hole such as the hole HL1, the second polymer is deposited on the etching stop layer (bottom of the hole), so that the deposit film DP2 is formed thereat. The etching stop layer can be protected by this deposit film DP2.

Further, if at least one of a CO gas, a CO₂ gas, an O₂ gas, a N₂ gas or a H₂ gas is added to the second gas, a width of the opening of the hole such as the hole HL1 may be easily adjusted.

Particularly, if at least one of the CO gas or the CO₂ gas is added to the second gas, CO or CO₂ bonds with the fluorine atom of the second polymer, so that COF₂ is generated. In such a case, fluorine atoms in the second polymer and the first polymer are scavenged, so that carbon atoms deposited on the bottom of the hole such as the hole HL1 may be relatively increased. Accordingly, in the process ST1 performed after the process ST2, the excessive etching upon the etching stop layer such as the etching stop layer ML1 can be effectively suppressed.

In the etching performed in the process ST1, selectivity with respect to the etching stop layer such as the etching stop layer ML1 is comparatively low. Further, in the etching performed in the process ST1, the opening (opening OP1, etc.) of the second layer LY2 (mask) may be clogged, and the etching may not be carried on. As a resolution, by performing the process ST2 after carrying out the process ST1 appropriately, the opening (opening OP1, etc.) of the second layer LY2 clogged in the process ST1 may be enlarged. Further, if the etching stop layer such as the etching stop layer ML1 is exposed through the hole such as the hole HL1, the protective film (second polymer) can be formed on this etching stop layer as a result of performing the process ST2.

Therefore, at the beginning of the process ST1 performed after the process ST2, the opening (opening OP1, etc.) of the second layer LY2 is already enlarged. At this time, if the etching stop layer such as the etching stop layer ML1 is exposed through the hole such as the hole HL1 in the etching of the process ST1, the protective film (second polymer) is already formed on this etching stop layer. Therefore, in the process ST1 performed after the process ST2, excessive etching upon the etching stop layer such as the etching stop layer ML1 can be suppressed by the protective film (second polymer) while the opening (opening OP1, etc.) of the second layer LY2 is suppressed from being clogged.

A processing time of the process ST2 may be, for example, 5 seconds to 30 seconds, for example, 10 seconds to 25 seconds. If the processing time of the process ST2 is relatively short (for example, shorter than 5 seconds), the deposit film DP2 may not be formed at the bottom of the hole such as the hole HL1 shown in FIG. 6. If the processing time of the process ST2 is relatively long (for example, longer than 30 seconds), on the other hand, the thickness of the deposit film DP2 may be excessively increased, and the etching upon the first layer LY1 may not be carried on in the process ST1 which may be performed after the process ST2 through the process ST3 to be described later. Further, if the processing time of the process ST2 is relatively long, the opening such as the opening OP1 may be excessively enlarged.

The high frequency power for plasma formation from the first high frequency power supply 62 in the process ST2 may be equal to or higher than, e.g., 2000 W. If the high frequency power is less than 2000 W, the etching stop layer may be excessively etched.

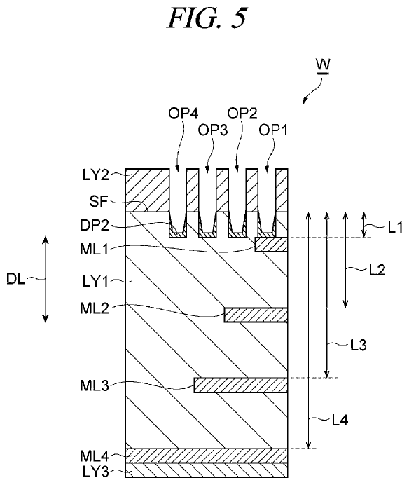

In the method MT, by performing the process ST3, the above-described processing sequence SQ can be performed repeatedly a preset number of times. In a first cycle of the processing sequence SQ the processing target object W having the structure shown in FIG. 4 is obtained from the processing target object W having the structure shown in FIG. 3 by the process ST1, and the processing target object W having the structure shown in FIG. 5 is obtained by the process ST2 which is performed after the process ST1. Further, by performing the processing sequence SQ the multiple times, the processing target object W having the structure shown in FIG. 6 can be obtained. Thus, by performing the method MT, the multiple number of holes (corresponding to the hole HL1, etc.) having the different lengths can be formed in parallel, not one by one. In such a case, during a period until the hole HL4 having the largest length from the top surface SF is formed, the clogging of the openings (opening OP1, etc.) can be avoided and the excessive etching upon the etching stop layer in the hole having the relatively short length can be suppressed. Further, in the first cycle of the processing sequence SQ, the hole HL1 of the opening OP1 need not necessarily reach the etching stop layer ML1 by the process ST1 as in the case where the processing target object W having the structure shown in FIG. 4 is obtained from the processing target object W having the structure shown in FIG. 3. Furthermore, the holes HL2 to HL4 of the openings OP2 to OP4 may etched deeper than a top surface of the etching stop layer ML1.

As stated above, by performing the method MT in which the processing sequence SQ is repeatedly performed the preset number of times, the holes (holes HL1 to HL4, etc.) having the different lengths can be formed in the first layer LY1 effectively, as shown in FIG. 6. As depicted in FIG. 6, by performing the method MT, the hole HL1 is formed in the first layer LY1 to reach the etching stop layer ML1 through the opening OP1 while the excessive etching upon the etching stop layer ML1 is suppressed.

The hole HL2 is formed in the first layer LY1 to reach the etching stop layer ML2 through the opening OP2 while the excessive etching upon the etching stop layer ML2 is suppressed. The hole HL3 is formed in the first layer LY1 to reach the etching stop layer ML3 through the opening OP3 while the excessive etching upon the etching stop layer ML3 is suppressed. The hole HL4 is formed in the first layer LY1 to reach the etching stop layer ML4 through the opening OP4.

According to the exemplary embodiment, it is possible to form a plurality of holes having different lengths effectively in parallel.

So far, the various exemplary embodiments have been described. However, the exemplary embodiments are not limiting, and various omissions, substitutions and changes may be made. Further, other exemplary embodiments may be created by combining elements in the various exemplary embodiments.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A plasma processing method of processing a processing target object,
wherein the processing target object comprises a first layer and a second layer,
the second layer is provided with multiple openings and is provided on a top surface of the first layer,
the top surface is exposed through the multiple openings,
the first layer is provided with multiple etching stop layers,
within the first layer, lengths from the multiple etching stop layers to the top surface are different,
the first layer is made of silicon oxide,
the second layer is made of a material containing carbon,
wherein the method comprises a processing sequence which is performed repeatedly within a chamber of a plasma processing apparatus in which the processing target object is accommodated,
the processing sequence comprises:
etching the processing target object through the multiple openings with the second layer as a mask by forming plasma from a first gas; and
etching, after the etching by forming the plasma from the first gas, the processing target object by forming plasma from a second gas,
wherein the first gas includes a gas containing a carbon atom and a fluorine atom,
the second gas includes a gas containing a carbon atom, a fluorine atom and a hydrogen atom,
high-order fluorocarbon is generated by the plasma from the first gas in the etching performed by forming the plasma from the first gas, and
low-order fluorocarbon or low-order hydrofluorocarbon is generated by the plasma from the second gas in the etching performed by forming the plasma from the second gas.

2. The plasma processing method of claim 1,
wherein the first gas includes at least one of a C₄F₆gas or a C₄F₈ gas.

3. The plasma processing method of claim 1,
wherein the second gas includes at least one of a CHF₃ gas, a CH₂F₂ gas or a CH₃F gas.

4. The plasma processing method of claim 3,
wherein the second gas further includes at least one of a CO gas, a CO₂ gas, an O₂ gas, a N₂ gas, or a H₂ gas.

5. The plasma processing method of claim 1,
wherein the etching stop layer is made of tungsten.

6. The plasma processing method of claim 1,
wherein the high-order fluorocarbon attaches mainly on the second layer in the etching performed by forming the plasma from the first gas, and
when the etching stop layer is exposed through a hole formed by performing the processing sequence, the low-order fluorocarbon or the low-order hydrofluorocarbon attaches on the etching stop layer through the hole in the etching performed by forming the plasma from the second gas.

7. A plasma processing apparatus, comprising:
a chamber;
a placing table provided within the chamber;
a gas supply system configured to supply a first gas and a second gas into the chamber;
a high frequency power supply configured to supply a high frequency power to excite the first gas and the second gas; and
a controller configured to control the gas supply system and the high frequency power supply,
wherein the controller controls the gas supply system and the high frequency power supply to perform a processing sequence repeatedly to etch a processing target object, which is placed on the placing table and provided with a first layer and a second layer, by forming plasma from the first gas and plasma from the second gas,
the second layer is provided with multiple openings and is provided on a top surface of the first layer,
the top surface is exposed through the multiple openings,
the first layer is provided with multiple etching stop layers,
within the first layer, lengths from the multiple etching stop layers to the top surface are different,
the first layer is made of silicon oxide,
the second layer is made of a material containing carbon, and
the processing sequence comprises:
etching the processing target object through the multiple openings with the second layer as a mask by forming plasma from the first gas; and
etching, after the etching by forming the plasma from the first gas, the processing target object by forming plasma from the second gas,
wherein the first gas includes a gas containing a carbon atom and a fluorine atom,
the second gas includes a gas containing a carbon atom, a fluorine atom and a hydrogen atom,
high-order fluorocarbon is generated by the plasma from the first gas in the etching performed by forming the plasma from the first gas, and
low-order fluorocarbon or low-order hydrofluorocarbon is generated by the plasma from the second gas in the etching performed by forming the plasma from the second gas.

8. The plasma processing apparatus of claim 7,
wherein the first gas includes at least one of a C₄F₆gas or a C₄F₈ gas.

9. The plasma processing apparatus of claim 7,
wherein the second gas includes at least one of a CHF₃ gas, a CH₂F₂ gas or a CH₃F gas.

10. The plasma processing apparatus of claim 9,
wherein the second gas further includes at least one of a CO gas, a CO₂ gas, an O₂ gas, a N₂ gas, or a H₂ gas.

11. The plasma processing method of claim 7,
wherein the high-order fluorocarbon attaches mainly on the second layer in the etching performed by forming the plasma from the first gas, and
when the etching stop layer is exposed through a hole formed by performing the processing sequence, the low-order fluorocarbon or the low-order hydrofluorocarbon attaches on the etching stop layer through the hole in the etching performed by forming the plasma from the second gas.

12. The plasma processing method of claim 2,
wherein the second gas includes at least one of a CHF₃ gas, a CH₂F₂ gas or a CH₃F gas.

13. The plasma processing method of claim 12,
wherein the second gas further includes at least one of a CO gas, a CO₂ gas, an O₂ gas, a N₂ gas, or a H₂ gas.

14. The plasma processing method of claim 13,
wherein the etching stop layer is made of tungsten.

15. The plasma processing method of claim 14,
wherein the high-order fluorocarbon attaches mainly on the second layer in the etching performed by forming the plasma from the first gas, and
when the etching stop layer is exposed through a hole formed by performing the processing sequence, the low-order fluorocarbon or the low-order hydrofluorocarbon attaches on the etching stop layer through the hole in the etching performed by forming the plasma from the second gas.

16. The plasma processing apparatus of claim 8,
wherein the second gas includes at least one of a CHF₃ gas, a CH₂F₂ gas or a CH₃F gas.

17. The plasma processing apparatus of claim 16,
wherein the second gas further includes at least one of a CO gas, a CO₂ gas, an O₂ gas, a N₂ gas, or a H₂ gas.

18. The plasma processing method of claim 17,
wherein the high-order fluorocarbon attaches mainly on the second layer in the etching performed by forming the plasma from the first gas, and
when the etching stop layer is exposed through a hole formed by performing the processing sequence, the low-order fluorocarbon or the low-order hydrofluorocarbon attaches on the etching stop layer through the hole in the etching performed by forming the plasma from the second gas.
